(19) United States
(12) Patent Application Publication
(10) Pub. No.: US 2026/0326260 A1
(43) Pub. Date: Oct. 22, 2026

(54) SYSTEMS AND METHODS FOR CONTROLLING A TEMPERATURE OF SUBSTRATE POLISHING OPERATIONS

(71) Applicant: Applied Materials, Inc., Santa Clara, CA (US)

(72) Inventors: Ashwin Chockalingam, San Jose, CA (US); Miroslav Gelo, Oakley, CA (US); Nick Jackson, Santa Clara, CA (US)

(73) Assignee: Applied Materials, Inc., Santa Clara, CA (US)

(21) Appl. No.: 19/650,025

(22) Filed: Apr. 16, 2026

Related U.S. Application Data
(60) Provisional application No. 63/792,789, filed on Apr. 22, 2025.

(51) Int. Cl. B24B 37/015; B24B 55/02; B24B 57/02; H10P 52/40

(52) U.S. Cl. CPC B24B 37/015; B24B 55/02; B24B 57/02; H10P 52/40

(57) ABSTRACT

Exemplary chemical mechanical polishing slurry delivery assemblies may include a slurry source. The assemblies may include a cooling fluid source. The assemblies may include a heat exchanger having a body that defines a slurry delivery lumen and a cooling lumen. The slurry delivery lumen may include a slurry inlet and a slurry outlet. The cooling lumen may include a cooling inlet and a cooling outlet. The slurry inlet may be fluidly coupled with the slurry source. The cooling inlet and the cooling outlet may be fluidly coupled with the cooling fluid source. The assemblies may include a slurry nozzle coupled with the slurry outlet.

### CROSS-REFERENCE TO RELATED APPLICATIONS

This application claims benefit of U.S. Provisional Patent Application No. 63/792,789, entitled, “SYSTEMS AND METHODS FOR CONTROLLING A TEMPERATURE OF SUBSTRATE POLISHING OPERATIONS,” filed Apr. 22, 2025, the contents of which are hereby incorporated by reference in their entirety.

### TECHNICAL FIELD

The present technology relates to semiconductor systems, processes, and equipment. More specifically, the present technology relates to the polishing of films deposited on a substrate.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications (e.g., planarization of a dielectric layer for photolithography), an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. Abrasive polishing slurry is typically supplied to the surface of the polishing pad.

One problem in CMP is that contact between the substrate, slurry, and polishing pad generates heat. This excess heat reduces the efficiency of the polishing process and may consume higher volumes of polishing slurry to maintain high substrate polishing throughput.

Thus, there is a need for improved systems and methods that can be used to dissipate heat generating during polishing operations. These and other needs are addressed by the present technology.

### SUMMARY

Exemplary chemical mechanical polishing slurry delivery assemblies may include a slurry source. The assemblies may include a cooling fluid source. The assemblies may include a heat exchanger having a body that defines a slurry delivery lumen and a cooling lumen. The slurry delivery lumen may include a slurry inlet and a slurry outlet. The cooling lumen may include a cooling inlet and a cooling outlet. The slurry inlet may be fluidly coupled with the slurry source. The cooling inlet and the cooling outlet may be fluidly coupled with the cooling fluid source. The assemblies may include a slurry nozzle coupled with the slurry outlet.

In some embodiments, the assemblies may include a slurry delivery line extending between and fluidly coupling an output of the slurry source with the slurry inlet of the heat exchanger. The slurry delivery lumen may extend through a central region of the body. The cooling lumen may be disposed radially outward of the slurry delivery lumen. The slurry delivery lumen may include a plurality of parallel slurry lines that extend between and fluidly couple the slurry inlet and the slurry outlet. The cooling lumen may extend about the plurality of parallel slurry lines. The cooling fluid source may be configured to control one or both of a temperature and a flow rate of a cooling fluid supplied to the heat exchanger. The cooling inlet and the cooling outlet may be rotatable relative to a main portion of the body.

Some embodiments of the present technology may encompass chemical mechanical polishing systems. The systems may include a polishing pad. The systems may include a slurry source. The systems may include a cooling fluid source. The systems may include a heat exchanger having a body that defines a slurry delivery lumen and a cooling lumen. The slurry delivery lumen may include a slurry inlet and a slurry outlet. The cooling lumen may include a cooling inlet and a cooling outlet. The slurry inlet may be fluidly coupled with the slurry source. The cooling inlet and the cooling outlet may be fluidly coupled with the cooling fluid source. The systems may include a slurry nozzle coupled with the slurry outlet. The slurry nozzle may be disposed over a portion of the polishing pad.

In some embodiments, the systems may include a temperature sensor that is configured to monitor a temperature of the polishing pad. The systems may include a controller that is configured to adjust one or both of a temperature and a flowrate of a cooling fluid delivered from the cooling fluid source to the cooling lumen of the heat exchanger based on data from the temperature sensor. The temperature sensor may include an IR sensor. The systems may include a substrate polishing head that is configured to rotate and translate against the polishing pad. The temperature sensor may be configured to monitor a temperature of the polishing pad proximate the substrate polishing head. The cooling fluid source may be configured to deliver a cooling fluid to the cooling lumen of the heat exchanger while a polishing slurry is delivered through the slurry delivery lumen and out the slurry nozzle. The systems may include a platen that supports the polishing pad. The platen may define a cooling lumen.

Some embodiments of the present technology may encompass methods of polishing a substrate. The methods may include flowing a polishing slurry into a slurry delivery lumen of a heat exchanger. The methods may include flowing a cooling fluid into a cooling lumen of the heat exchanger. The methods may include delivering the polishing slurry from the heat exchanger to a polishing pad. The methods may include polishing a substrate atop the polishing pad.

In some embodiments, a temperature of the cooling fluid may be between 5 °C and 19 °C. Polishing the substrate may include one or both of rotating the polishing pad and rotating the substrate. The methods may include monitoring a torque between the substrate and the polishing pad. The methods may include adjusting one or both of a rotational speed of the polishing pad and a rotational speed of the substrate when the torque exceeds a predetermined threshold. The methods may include monitoring a temperature of the polishing pad. The methods may include adjusting one or both of a temperature and a flowrate of the cooling fluid delivered from a cooling fluid source to the cooling lumen of the heat exchanger based on the temperature of the polishing pad. A flowrate of the cooling fluid may be between 0.25 lpm and 2 lpm.

Such technology may provide numerous benefits over conventional systems and techniques. For example, the slurry delivery assemblies described herein may more effectively cool the slurry prior to delivery to the polishing pad. The cooled slurry may help dissipate heat generated by contact between the substrate, slurry, and polishing pad during polishing operations. The improved heat dissipation from the cooled may enable less slurry to be used, which may significantly reduce the cost and waste of slurry. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary polishing system according to some embodiments of the present technology.

FIG. 2 shows a schematic partial cross-sectional view of an exemplary polishing system according to some embodiments of the present technology.

FIG. 2A shows a schematic partial cross-sectional view of a heat exchanger of the polishing system of FIG. 2 according to some embodiments of the present technology.

FIG. 2B shows a schematic partial cross-sectional view of a heat exchanger of the polishing system of FIG. 2 according to some embodiments of the present technology.

FIG. 3A shows a schematic partial cross-sectional view of an exemplary heat exchanger according to some embodiments of the present technology.

FIG. 3B shows a schematic partial cross-sectional view of an exemplary heat exchanger according to some embodiments of the present technology.

FIG. 3C shows a schematic partial cross-sectional view of an exemplary heat exchanger according to some embodiments of the present technology.

FIG. 3D shows a schematic partial cross-sectional view of an exemplary heat exchanger according to some embodiments of the present technology.

FIG. 3E shows a schematic partial cross-sectional view of an exemplary heat exchanger according to some embodiments of the present technology.

FIG. 4 is a flowchart of an exemplary method of polishing a substrate according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In conventional chemical mechanical polishing (CMP) operations an abrasive slurry is typically delivered to a polishing pad. Abrasive particles within the slurry are used to remove and polish a surface of films deposited on a substrate. For example, the substrate and polishing pad may be rotated and/or translated relative to one another while downward pressure is applied to the substrate. The rough surface of the polishing pad, as well as the abrasive nature of the particles within the slurry, helps remove material from the surface of the substrate in a controlled manner. However, the removal of material generates heat due to friction generated by the sliding contact of the three materials. This heat may impact the speed and efficiency of the polishing operations. For example, the excess heat may reduce the rate of removal of material from the surface of the substrate. Additionally, high temperatures may lead to excessive wear of components of the polishing system and may cause localized stress concentrations on the substrate, which can lead to system and/or substrate damage. To help reduce the impact of heat, some conventional polishing systems may significantly increase the amount of polishing slurry used. However, such solutions result in excessive use and waste of polishing slurry. Some conventional polishing solutions may apply a cooling fluid, such as deionized water, to a surface of the cooling pad in the form of an atomized mist. When the fluid droplets reach the polishing pad, the droplets undergo a phase change that helps dissipate heat from the polishing pad. However, such techniques are not particularly efficient (e.g., due to the poor thermal conductivity of the polishing pad) at dissipating heat and also enable the cooling fluid to contact and dilute the polishing slurry.

The present technology overcomes these issues with conventional polishing systems by integrating a heat exchanger proximate a dispensing nozzle of the slurry delivery mechanism. The heat exchanger may receive a flow of cooling fluid that may be used to cool the polishing slurry prior to delivery to the polishing pad. For example. the heat exchanger may be formed from a thermally conductive material that enables the cooling fluid to cool the body of the heat exchanger, and subsequently, a polishing slurry passed through the heat exchanger. This may help reduce the temperature of the polishing slurry without diluting the slurry. Additionally, embodiments may include a torque mitigation system that may help maintain the torque generated as the substrate rotates against the polishing pad stays within a predetermined range. This may help control heat generated during the polishing process. Embodiments may therefore ensure that temperature changes during the polishing operation are reduced or eliminated, which may help maintain a consistent polishing temperature and polishing rate. This enables the polishing slurry to be provided at low flow rates, which may help reduce slurry usage and waste relative to conventional high flow polishing operations.

Although the remaining disclosure will routinely identify specific slurry delivery mechanisms utilizing the disclosed technology, it will be readily understood that the systems and methods are equally applicable to a variety of other semiconductor processing operations and systems. Accordingly, the technology should not be considered to be so limited as for use with the described polishing systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

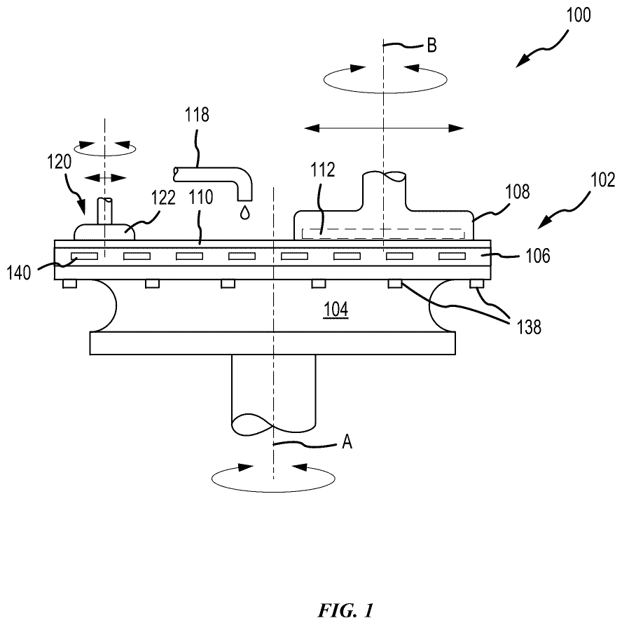

FIG. 1 shows a schematic cross-sectional view of an exemplary polishing system 100 according to some embodiments of the present technology. Polishing system 100 includes a platen assembly 102, which includes a lower platen 104 and an upper platen 106. Lower platen 104 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 104, and which may access upper platen 106 through a backside of the upper platen. For example, the upper platen 106 may define or otherwise include one or more cooling lumens 140. The cooling lumens 140 may extend within an interior of the upper platen 106 and may be fluidly coupled with a cooling fluid source that may circulate a cooling fluid within the cooling lumen 140 to help cool the upper platen 106 and a polishing pad 110 mounted on a first surface of the upper platen 106. A substrate carrier 108, or carrier head or substrate polishing head, may be disposed above the polishing pad 110 and may face the polishing pad 110. The platen assembly 102 may be rotatable about an axis A, while the substrate carrier 108 may be rotatable about an axis B. The substrate carrier may also be configured to sweep back and forth from an inner radius to an outer radius along the platen assembly, which may, in part, reduce uneven wear of the surface of the polishing pad 110. The polishing system 100 may also include a fluid delivery arm 118 positioned above the polishing pad 110, and which may be used to deliver polishing fluids, such as a polishing slurry, onto the polishing pad 110. Additionally, a pad conditioning assembly 120 may be disposed above the polishing pad 110 and may face the polishing pad 110.

In some embodiments of performing a chemical-mechanical polishing process, the rotating and/or sweeping substrate carrier 108 may exert a downforce against a substrate 112, which is shown in phantom and may be disposed within or coupled with the substrate carrier. The downward force applied may depress a material surface of the substrate 112 against the polishing pad 110 as the polishing pad 110 rotates about a central axis of the platen assembly. The interaction of the substrate 112 against the polishing pad 110 may occur in the presence of one or more polishing fluids delivered by the fluid delivery arm 118. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 112.

The pad conditioning assembly 120 may be operated to apply a fixed abrasive conditioning disk 122 against the surface of the polishing pad 110, which may be rotated as previously noted. The conditioning disk may be operated against the pad prior to, subsequent, or during polishing of the substrate 112. Conditioning the polishing pad 110 with the conditioning disk 122 may maintain the polishing pad 110 in a desired condition by abrading, rejuvenating, and removing polish byproducts and other debris from the polishing surface of the polishing pad 110. Upper platen 106 may be disposed on a mounting surface of the lower platen 104 and may be coupled with the lower platen 104 using a plurality of fasteners 138, such as extending through an annular flange shaped portion of the lower platen 104.

The polishing platen assembly 102, and thus the upper platen 106, may be suitably sized for any desired polishing system, and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for a polishing platen 106 sized for concurrent polishing of multiple substrates. The upper platen 106 may be characterized by a thickness of between about 20 mm and about 150 mm and may be characterized by a thickness of less than or about 100 mm, such as less than or about 80 mm, less than or about 60 mm, less than or about 40 mm, or less. In some embodiments, a ratio of a diameter to a thickness of the polishing platen 106 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, light-weight, and polishing fluid corrosion-resistant material, such as aluminum, an aluminum alloy, or stainless steel, although any number of materials may be used. Polishing pad 110 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 100 is included to provide suitable reference to components discussed below, which may be incorporated in system 100, although the description of polishing system 100 is not intended to limit the present technology in any way, as embodiments of the present technology may be incorporated in any number of polishing systems that may benefit from the components and/or capabilities as described further below.

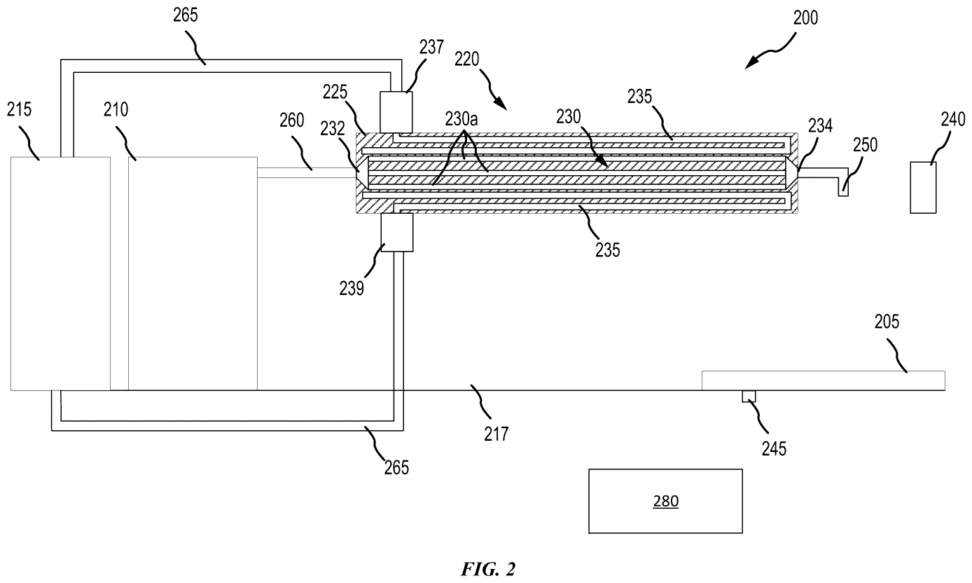

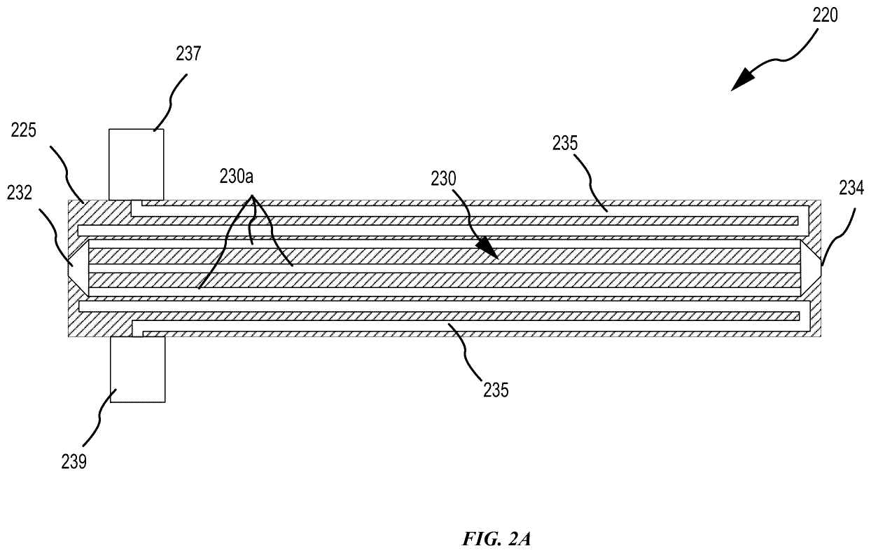

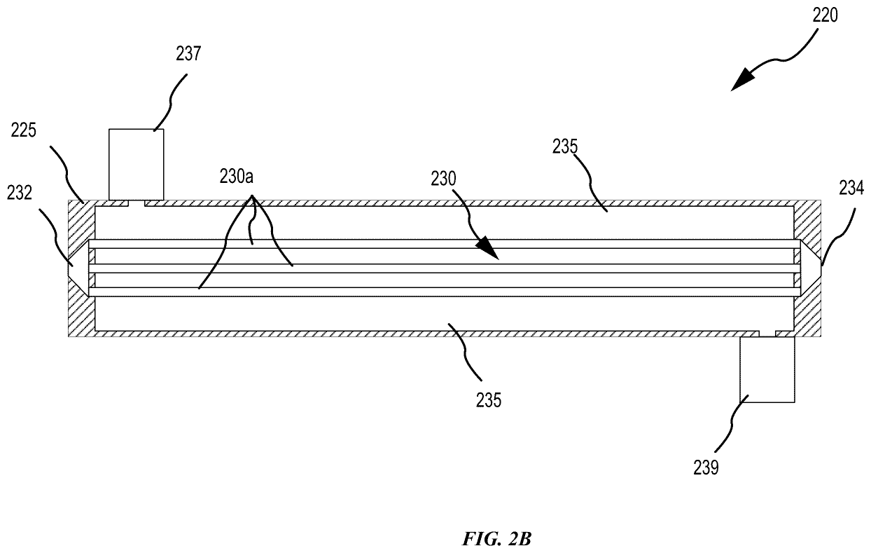

FIG. 2 illustrates a schematic cross-sectional partial view of a polishing system 200 according to some embodiments of the present technology. Polishing system 200 may show a partial view of the components being discussed and may include other features, such as any of the features described in relation to polishing system 100. Polishing system 200 may include a slurry fluid source 210, which may include a reservoir that holds a volume of polishing slurry. The polishing slurry may be an abrasive polishing slurry that is delivered to a polishing pad 205, which may be similar to polishing pad 110 in some embodiments. The polishing slurry may include abrasive particles that provide grit that helps the polishing pad 205 to polish the film on the substrate. For example, the slurry may include a nano-sized abrasive powder dispersed in a chemically reactive solution, which may enable the solution to chemically etch and soften the film while the abrasive particles mechanically abrade and/or otherwise remove a portion of the film to planarize and/or otherwise alter a surface of a substrate. The slurry fluid source 210 may also include a pump and/or other positive pressure source that may be used to selectively flow the polishing slurry to the polishing pad 205. The polishing slurry may be delivered continuously and/or intermittently during a given polishing operation.

Polishing system 200 may include a cooling fluid source 215 that may include a reservoir that holds a volume of a cooling fluid. The cooling fluid may include various fluids, such as (but not limited to) process chilled water. The cooling fluid may be used to cool the polishing slurry prior to the polishing slurry being delivered to the polishing pad as will be discussed in greater detail below. The cooling fluid source 215 may also include a pump and/or other positive pressure source that may be used to control a flow rate of the cooling fluid. Additionally, the cooling fluid source 215 may include a chiller module that may be used to control a temperature of the cooling fluid. This enables the flow rate and/or temperature of the cooling fluid to be adjusted in situ to control a temperature of the slurry to maintain a temperature of the polishing pad within a predetermined range during polishing operations.

Polishing system 200 may include a heat exchanger 220 that may be coupled between the slurry fluid source 210 and a slurry nozzle 250 that is positioned above and delivers the polishing slurry to an upper surface of the polishing pad 205. For example, the heat exchanger 220 may include a body 225 that defines a slurry delivery lumen 230. The slurry delivery lumen 230 may include a slurry inlet 232 and a slurry outlet 234. The slurry inlet 232 may be fluidly coupled with the slurry fluid source 210. For example, a slurry delivery line 260 may extend between and fluidly couple an outlet of the slurry fluid source 210 with the slurry inlet 232. The slurry nozzle 250 may be coupled with the slurry outlet 234. In some embodiments, the heat exchanger 220 may be positioned within 10 cm of the slurry nozzle 250, which may ensure that the polishing slurry does not significantly heat up between the time the polishing slurry leaves the heat exchanger 220 and contacts the polishing pad 205. Such a design enables polishing slurry to be pumped or otherwise flowed from the slurry fluid source 210 and onto the polishing pad 205 via the slurry delivery line 260, slurry delivery lumen 230, and slurry nozzle 250. In some embodiments, the slurry delivery lumen 230 may include a single lumen that extends between and fluidly couples the slurry inlet 232 with the slurry outlet 234. The slurry delivery lumen 230 may be linear and/or may include one or more coils or other non-linear regions. In some embodiments, the slurry delivery lumen 230 may include a number of slurry lines 230a that extend between and fluidly couple the slurry inlet 232 and the slurry outlet 234. For example, as illustrated, three slurry lines 230a extend between and fluidly couple the slurry inlet 232 and the slurry outlet 234, although other number of slurry lines are possible in various embodiments. For example, the slurry delivery lumen 230 may include one or more slurry lines, two or more slurry lines, three or more slurry lines, four or more slurry lines, five or more slurry lines, six or more slurry lines, or more. The slurry lines 230a may extend parallel to one another in some embodiments, while in other embodiments, one or more of the slurry lines 230a may not be parallel. The slurry lines 230a may be linear or non-linear in various embodiments. The body 225 may define or include a manifold that splits the flow from the slurry inlet 232 to any number of slurry lines 230a and a manifold that consolidates any number of slurry lines 230a to the slurry outlet 234.

The body 225 of the heat exchanger 220 may define a cooling lumen 235. The cooling lumen 235 may include a cooling inlet 237 and a cooling outlet 239. Both the cooling inlet 237 and the cooling outlet 239 may be fluidly coupled with the cooling fluid source 215. For example, one or more cooling lines 265 may extend between and fluidly couple an outlet of the cooling fluid source 215 with the cooling inlet 237 and an inlet of the cooling fluid source 215 with the cooling outlet 239. This enables cooling fluid to be pumped or otherwise flowed from the cooling fluid source 215, through the cooling lumen 235 of the heat exchanger 220 and return back to the cooling fluid source 215. In this manner, the cooling fluid may be circulated through the cooling circuit to chill the body 225 of the heat exchanger 220. To facilitate cooling of the body 225 of the heat exchanger 220 and the slurry delivery lumen 230, the body 225 may be formed from a thermally conductive material. In some embodiments, a thermal conductivity of the body 225 may be at least 10 W/mK, at least 20 W/mK, at least 30 W/mK, at least 40 W/mK, at least 50 W/mK, at least 60 W/mK, at least 70 W/mK, at least 80 W/mK, at least 90 W/mK, at least 100 W/mK, at least 125 W/mK, at least 150 W/mK, at least 175 W/mK, at least 200 W/mK, at least 250 W/mK/at least 300 W/mK, at least 350 W/mK, at least 400 W/mK, or more, with greater thermal conductivities providing higher rates of heat transfer. For example, the body 225 may be formed from aluminum, copper, stainless steel, and/or other metallic material in some embodiments. Such materials may enable the cooling fluid flowed within the cooling lumen 235 to cool the body 225 and polishing slurry flowed within the slurry delivery lumen 230. The material of the body, and in particular a portion of the body 225 that defines the slurry delivery lumen 230, may be formed from and/or coated with a material that is chemically inert with respect to the polishing slurry.

The geometry of the cooling lumen 235 may be selected to promote effective cooling of the slurry delivery lumen 230 and polishing slurry flowed within. For example, in some embodiments, the slurry delivery lumen 230 may extend through a central region of the body 225, while the cooling lumen 235 may be disposed radially outward of and in close proximity to the slurry delivery lumen 230, although other designs are possible, including those in which the slurry delivery lumen 230 is disposed radially outward of one or more portions of the cooling lumen 235. In some embodiments, the cooling lumen 235 may include one or more linear segments that extend along a portion of a length of the slurry delivery lumen 230. For example, as shown in FIG. 2A, a number of linear segments may zigzag between a proximal end of the body 225 and a distal end of the body 225. Walls or other partitions may separate each adjacent segment to direct the flow of cooling fluid along a length of the cooling lumen 235. Each segment may be a linear tube and/or may define an annular and/or arcuate channel that extends along at least a portion of the length of the body 225. In other embodiments, such as shown in FIG. 2B, the cooling lumen 235 may include a plenum that extends about the slurry delivery lumen 230 (or segments thereof), with one end of the plenum being fluidly coupled with the cooling inlet 237 and the other end of the plenum being fluidly coupled with the cooling outlet 239. Such a design may enable the cooling fluid to contact walls of the slurry delivery lumen 230 (or segments thereof). It will be appreciated that other designs of the cooling lumen 235 are possible in various embodiments. For example, while shown as being generally linear, the cooling lumen 235 and/or segments thereof may be curved in some embodiments. As just one example, the cooling lumen 235 may include one or more coils that extend circumferentially about the slurry delivery lumen 230 and/or one or more slurry lines 230a thereof. The coils may extend along substantially all or other portion of a length of the slurry delivery lumen 230 in various embodiments. The cooling lumen 235 and the slurry delivery lumen 230 may be fluidly isolated from one another, which may enable the cooling fluid to cool the polishing slurry without diluting the polishing slurry. Cooling of the polishing slurry may also increase a viscosity of the polishing slurry, which may cause the polishing slurry to flow more slowly within the heat exchanger 220. The slower flow of the polishing slurry may increase the time in which the polishing slurry is disposed within the heat exchanger 220 and may increase the ability of the cooling fluid to chill the polishing slurry.

The heat exchanger 220 may operate as a parallel flow and/or a counterflow heat exchanger. For example, the cooling inlet 237, cooling lumen 235, and cooling outlet 239 may be positioned such that the flow of cooling fluid is parallel to the direction of flow of the polishing slurry. In other embodiments, the cooling inlet 237, cooling lumen 235, and cooling outlet 239 may be positioned such that the flow of cooling fluid is opposite the direction of flow of the polishing slurry. In other embodiments, the design of the cooling inlet 237, cooling lumen 235, and cooling outlet 239 may create different regions of parallel, counter, and/or cross flow. In some embodiments, one or both of the cooling inlet 237 and the cooling outlet 239 may be rotatable and/or otherwise repositionable relative to the body 225. This may enable the angular position of the cooling inlet 237 and/or the cooling outlet 239 to be adjusted relative to the body 225 to facilitate coupling of the slurry delivery line 260 and/or cooling line 265 with the body 225.

Polishing system 200 may include a number of sensors that may be used to monitor one or more parameters of the polishing process. For example, the sensors may include one or more temperature sensors 240 that are configured to monitor a temperature of the polishing pad 205. In some embodiments, the temperature sensors 240 may be positioned and/or oriented to monitor the temperature of the polishing pad 205 proximate the carrier head. The temperature sensors 240 may take various forms. For example, the temperature sensors 240 may include infrared (IR) sensors, thermocouples, thermistors, and/or other temperature sensors, which may be coupled with, embedded within, and/or pointed at the polishing pad 205 and/or a platen that supports the polishing pad 205, such as upper platen 106 of polishing system 100. Polishing system 200 may include one or more torque sensors 245 that may be configured to monitor a torque that is generated from interactions between the substrate and the polishing pad 205 as the two materials are rotated relative to one another. The torque may be a function of the relative speed of rotation, a position of the substrate (and carrier head) relative to a central axis of the polishing pad 205, and/or an amount of downforce applied to the substrate by the carrier head. The torque sensors 245 may be disposed in the carrier head, polishing pad 205, platen supporting the polishing pad 205, in the rotational actuator of the carrier head and/or platen, and/or in other locations in various embodiments.

The operation of polishing system 200 may be controlled by a computer system 280. The computer system 280 may include any device or combination of devices configured to implement the operations described herein. Accordingly, the computer system 280 may be a controller or array of controllers and/or a computer configured with software stored on a non-transitory, computer-readable medium that, when executed, may perform the operations described in relation to methods according to embodiments of the present technology. The polishing system 200 may be configured to perform one or more process operations in the fabrication of a semiconductor structure. More specifically, the polishing system 200 may be outfitted to remove material from the surface of the substrate after various processing operations, such as to planarize the surface of the substrate.

The computer system 280 may be communicatively coupled with the temperature sensors 240 and/or torque sensors 245 and may use data from such sensors to control operation of the polishing system 200. For example, the computer system 280 may adjust a temperature and/or a flowrate of the cooling fluid delivered from the cooling fluid source 215 to the cooling lumen 235 of the heat exchanger 220 based on data from the temperature sensor 240 to maintain the temperature of the polishing pad 205 within a predefined range. Similarly, the computer system 280 may adjust a rotational speed of the carrier head, a rotational speed of the platen, and/or a downforce applied by the carrier head based on data from the torque sensor 245 to maintain the torque within a predefined range, which may help limit the generation of heat during polishing operations.

In operation, the cooling fluid source 215 may deliver cooling fluid to the cooling lumen 235 as the slurry fluid source 210 delivers polishing slurry to the slurry delivery lumen 230. The cooling fluid may chill the body 225 of the heat exchanger 220, which may subsequently cool the polishing slurry without diluting the polishing slurry. As noted above, the computer system 280 may adjust various parameters of the cooling fluid delivery based on the temperature of the polishing pad 205. This may enable the temperature of the polishing pad 205 to be maintained within a desired range and may prevent the temperature from increasing by an unacceptable amount, which would otherwise require more slurry to be consumed by the polishing process. Similarly, the computer system 280 may adjust one or more parameters of the carrier head and/or platen to control an amount of torque generated during the polishing process, which may help control the amount of heat generated. Together, this may enable the temperature of the polishing pad to be carefully controlled and may enable significantly lower flow rates and volumes of polishing slurry to be used in a given polishing operation. For example, embodiments of the present invention may help reduce the volume of polishing slurry needed to maintain a similar removal rate by up to 70% relative to conventional polishing systems. For example, where 100 cc of polishing slurry is used in conventionally cooled polishing systems, the use of heat exchangers as described herein may reduce the volume of polishing slurry needed to as low as 30 cc. This helps maintain higher polishing rates to maintain high substrate throughput while significantly reducing the amount of polishing slurry needed. In some embodiments, in addition to chilling the slurry via the heat exchanger 220, the platen on which the polishing pad 205 is seated may be actively chilled, such as by circulating a cooling fluid through one or more cooling channels formed in the platen.

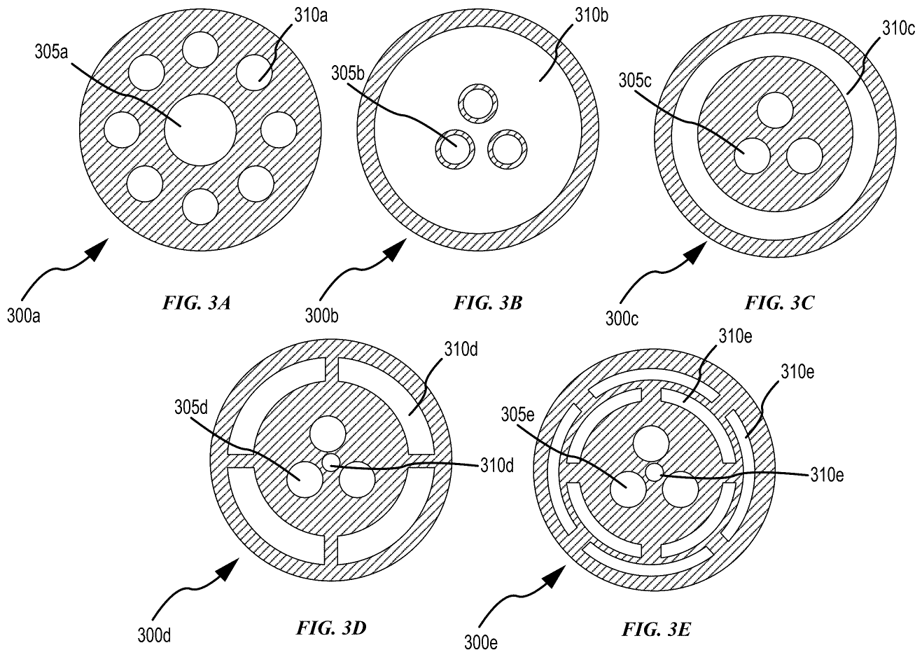

FIGS. 3A-3E illustrate cross-sectional views of heat exchangers 300 according to embodiments of the present technology. The heat exchangers 300 may be used in polishing systems, such as polishing systems 100 and 200. For example, the heat exchangers 300 may be used as heat exchanger 220 and may include any of the features described in relation to heat exchanger 220. FIG. 3A illustrates a heat exchanger 300a having a slurry delivery lumen 305a having a single linear segment disposed along a central axis of the heat exchanger 300a. The heat exchanger 300a includes a cooling lumen 310a having a series of linear tubular segments, which are arranged radially about the slurry delivery lumen 305a. FIG. 3B illustrates a heat exchanger 300b having a slurry delivery lumen 305b formed from a number of linear segments disposed radially about a central axis of the heat exchanger 300b. The heat exchanger 300b includes a cooling lumen 310b that includes single plenum formed about the slurry delivery lumen 305b. FIG. 3C illustrates a heat exchanger 300c having a slurry delivery lumen 305c formed from a number of linear segments disposed radially about a central axis of the heat exchanger 300c. The heat exchanger 300c includes a cooling lumen 310c that is coiled about the segments of the slurry delivery lumen 305c. FIG. 3D illustrates a heat exchanger 300d having a slurry delivery lumen 305d formed from a number of linear segments disposed radially about a central axis of the heat exchanger 300d. The heat exchanger 300d includes a cooling lumen 310d that includes a number of annular channels formed about the slurry delivery lumen 305d. The cooling lumen 310d may also include one or more annular channels and/or circular channels that are disposed radially inward of the segments of the slurry delivery line 305d. FIG. 3E illustrates a heat exchanger 300e having a slurry delivery lumen 305e formed from a number of linear segments disposed radially about a central axis of the heat exchanger 300e. The heat exchanger 300e includes a cooling lumen 310e that includes a number of arcuate channels formed about the slurry delivery lumen 305e. Each arcuate channel may be at a same or different radial distance from a center of the heat exchanger 300e and may be at regular or irregular angular positions about the center of the heat exchanger 300e. The cooling lumen 310e may also include one or more arcuate channels and/or circular channels that are disposed radially inward of the segments of the slurry delivery line 305e.

It will be appreciated that the cross-sections shown in FIGS. 3A-3E are merely provided as examples of heat exchanger designs and that numerous exist. For example, the various features of FIGS. 3A-3E may be combined in any number of permutations. For example, the cooling lumen may coil about any combination of one or more segments of the slurry delivery lumen. In some embodiments, the slurry delivery lumen may include a centrally aligned segment in conjunction with any number of radially outward segments.

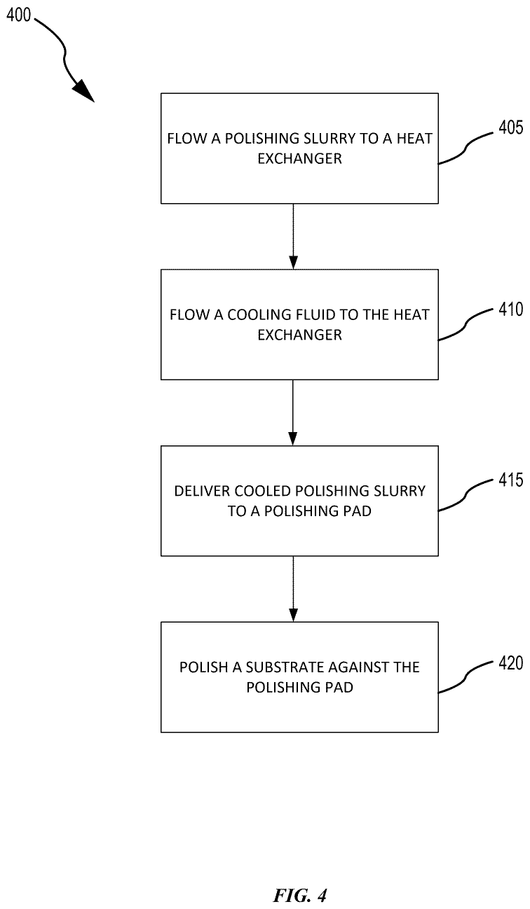

FIG. 4 shows exemplary operations in a method 400 for polishing a substrate according to some embodiments of the present technology. Method 400 may be performed using a polishing system, such as polishing systems 100 and 200 described herein. Method 400 may include operations prior to the substrate polishing in some embodiments. For example, prior to the polishing, a substrate may have one or more deposition and/or etching operations performed as well as any planarization or other process operations performed. Method 400 may include a number of operations that may be performed automatically within a system to limit manual interaction, and to provide increased efficiency and precision over manual operations. Method 400 may be performed in conjunction with a conventional CMP polishing process. In some embodiments, operations of method 400 may be controlled by a computer system, such as computer system 280.

Method 400 may include flowing a polishing slurry into a slurry delivery lumen of a heat exchanger at operation 405. For example, a slurry fluid source may pump or otherwise flow the polishing slurry to a slurry inlet of the heat exchanger. A flow rate of the polishing fluid may be a low flow rate, such as between 0.01 lpm and 0.1 lpm in some embodiments. However, it will be appreciated that the method 400 may be performed at high flow rates in some embodiments. For example, the flow rate of the polishing slurry may exceed 0.1 lpm in some embodiments. At operation 410, a cooling fluid may be flowed into a cooling lumen of the heat exchanger. For example, a cooling fluid source may pump or otherwise flow the cooling fluid to a cooling inlet of the heat exchanger. The cooling fluid may begin to be flowed before, simultaneous to, or after the polishing slurry is flowed to the heat exchanger. In some embodiments, the cooling fluid may be flowed from the cooling fluid source at a temperature of between 5 °C and 19 °C, although other temperatures are possible in various embodiments. A flow rate of the cooling fluid may be between 0.25 lpm and 2 lpm in some embodiments. The cooling fluid may cool a body of the heat exchanger, including walls that define a slurry delivery lumen that receives the polishing slurry. This enables the cooling fluid to effectively cool the polishing slurry. The cooled polishing slurry may be delivered to a polishing pad at operation 415. For example, the polishing slurry may be flowed through a slurry outlet of the heat exchanger and through a nozzle that expels the polishing slurry on a top surface of the polishing pad. The chilled polishing slurry may be delivered to the polishing pad continuously and/or periodically during the polishing operation.

At operation 420, a substrate may be polished atop the polishing pad. For example, the substrate may be positioned face (film side) down on a carrier head, which may rotate and/or laterally translate the face of the substrate against the polishing pad. Alternatively, or additionally, the polishing pad may be rotated relative to the carrier head. The chemical solution of the slurry may chemically etch and soften the film while the abrasive particles mechanically abrade and/or otherwise remove a portion of the film to planarize and/or otherwise alter a surface of the substrate.

In some embodiments, the flow of cooling fluid may be controlled via a feedback loop. For example, one or more temperature sensors may be used to monitor a temperature of the polishing pad, such as at a location proximate the carrier head and substrate. Based on the temperature of the polishing pad, the method 400 may include adjusting the temperature and/or the flowrate of the cooling fluid delivered from a cooling fluid source to the cooling lumen of the heat exchanger. For example, the polishing operation may have a predetermined acceptable polishing pad temperature range. In some embodiments, the temperature range may be a range of no greater than 10 degrees Celsius, no greater than 8 degrees Celsius, no greater than 6 degrees Celsius, no greater than 4 degrees Celsius, no greater than 2 degrees Celsius, or less. The temperature range may be based on a desired polishing rate, which may dictate an amount of torque needed. As the temperature of the polishing pad reaches and/or approaches an upper threshold of the range, the flow rate of the cooling fluid may be increased and/or a temperature of the cooling fluid supplied by the cooling fluid source may be reduced, which may increase the heat transfer between the cooling fluid, heat exchanger, and polishing slurry. This ultimately lowers the temperature of the polishing slurry and may help reduce the temperature of the polishing pad to keep the polishing pad temperature within the predetermined range. Similarly, as the temperature of the polishing pad reaches and/or approaches a lower threshold of the range, the flow rate of the cooling fluid may be decreased and/or a temperature of the cooling fluid supplied by the cooling fluid source may be increased, which may reduce the heat transfer between the cooling fluid, heat exchanger, and polishing slurry. This ultimately raises the temperature of the polishing slurry and may help increase the temperature of the polishing pad to keep the polishing pad temperature within the predetermined range. By using such a feedback loop, the temperature of the polishing slurry may be continuously adjusted to help maintain the temperature of the polishing pad within a narrow range (e.g., limit the temperature change of the polishing pad during polishing operations), which may help promote more even polishing rates. Additionally, the cooling processes described herein may enable sufficiently efficient and effective cooling of the polishing pad and polishing slurry to enable high polishing rates with low consumption of polishing slurry as compared to conventional polishing systems.

In some embodiments, the method 400 may include monitoring a torque between the substrate and the polishing pad. The method 400 may further include adjusting a rotational speed of the polishing pad, a rotational speed of the substrate, and/or a magnitude of downforce applied to the substrate when the torque falls below or exceeds a predetermined threshold. For example, if the torque falls below or approaches a lower threshold, the polishing removal rate may drop. To combat this, the rotational speed of the polishing pad and/or substrate may be increased and/or an amount of downforce applied to the substrate may be increased to increase the amount of torque to enable the polishing rate to be maintained at a desired level. Similarly, if the torque exceeds or approaches an upper threshold, the polishing removal rate may increase, but may also cause excessive heat, wear and/or damage to the substrate and/or components of the polishing system. To combat this, the rotational speed of the polishing pad and/or substrate may be decreased and/or an amount of downforce applied to the substrate may be reduced to decrease the amount of torque to enable the polishing rate to be maintained at a desired level. In such a manner, the torque, and subsequently polishing removal rate, may be carefully maintained within a narrow range. In some embodiments, the torque range may be similar to a high slurry flow polishing operation, which may help ensure that removal rates may be similar between the low slurry flow operations enabled by the use of a heat exchanger as described herein and conventional high slurry flow operations.

While described as using feedback loops to control the polishing pad temperature and system torque, it will be appreciated that in some instances the method 400 may be performed using predetermined operational parameters. For example, based on empirical and/or analytical data, a cooling fluid temperature, cooling fluid flow rate, polishing pad rotational speed, substrate rotational speed, and/or substrate downforce may be operated at predetermined levels that have been determined to maintain the polishing pad temperature, system torque, and polishing removal rate within desired ranges. The predetermined levels may be constant throughout an entire duration of the polishing operation or may vary throughout the duration of the polishing operation.

In some embodiments, to further cool the polishing pad, the method 400 may include circulating a cooling fluid within one or more cooling channels formed in a platen that supports the polishing pad.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the mesh” includes reference to one or more meshes and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A chemical mechanical polishing slurry delivery assembly, comprising:
a slurry source;
a cooling fluid source;
a heat exchanger comprising a body that defines a slurry delivery lumen and a cooling lumen, wherein:
the slurry delivery lumen comprises a slurry inlet and a slurry outlet; and
the cooling lumen comprises a cooling inlet and a cooling outlet;
the slurry inlet is fluidly coupled with the slurry source; and
the cooling inlet and the cooling outlet are fluidly coupled with the cooling fluid source; and
a slurry nozzle coupled with the slurry outlet.

2. The chemical mechanical polishing slurry delivery assembly of claim 1, further comprising:
a slurry delivery line extending between and fluidly coupling an output of the slurry source with the slurry inlet of the heat exchanger.

3. The chemical mechanical polishing slurry delivery assembly of claim 1, wherein:
the slurry delivery lumen extends through a central region of the body; and
the cooling lumen is disposed radially outward of the slurry delivery lumen.

4. The chemical mechanical polishing slurry delivery assembly of claim 1, wherein:
the slurry delivery lumen comprises a plurality of parallel slurry lines that extend between and fluidly couple the slurry inlet and the slurry outlet.

5. The chemical mechanical polishing slurry delivery assembly of claim 4, wherein:
the cooling lumen extends about the plurality of parallel slurry lines.

6. The chemical mechanical polishing slurry delivery assembly of claim 1, wherein:
the cooling fluid source is configured to control one or both of a temperature and a flow rate of a cooling fluid supplied to the heat exchanger.

7. The chemical mechanical polishing slurry delivery assembly of claim 1, wherein:
the cooling inlet and the cooling outlet are rotatable relative to a main portion of the body.

8. A chemical mechanical polishing system, comprising:
a polishing pad;
a slurry source;
a cooling fluid source;
a heat exchanger comprising a body that defines a slurry delivery lumen and a cooling lumen, wherein:
the slurry delivery lumen comprises a slurry inlet and a slurry outlet; and
the cooling lumen comprises a cooling inlet and a cooling outlet;
the slurry inlet is fluidly coupled with the slurry source; and
the cooling inlet and the cooling outlet are fluidly coupled with the cooling fluid source; and
a slurry nozzle coupled with the slurry outlet, the slurry nozzle being disposed over a portion of the polishing pad.

9. The chemical mechanical polishing system of claim 8, further comprising:
a temperature sensor that is configured to monitor a temperature of the polishing pad.

10. The chemical mechanical polishing system of claim 9, further comprising:
a controller that is configured to adjust one or both of a temperature and a flowrate of a cooling fluid delivered from the cooling fluid source to the cooling lumen of the heat exchanger based on data from the temperature sensor.

11. The chemical mechanical polishing system of claim 9, wherein:
the temperature sensor comprises an IR sensor.

12. The chemical mechanical polishing system of claim 9, further comprising:
a substrate polishing head that is configured to rotate and translate against the polishing pad, wherein the temperature sensor is configured to monitor a temperature of the polishing pad proximate the substrate polishing head.

13. The chemical mechanical polishing system of claim 8, wherein:
the cooling fluid source is configured to deliver a cooling fluid to the cooling lumen of the heat exchanger while a polishing slurry is delivered through the slurry delivery lumen and out the slurry nozzle.

14. The chemical mechanical polishing system of claim 8, further comprising:
a platen that supports the polishing pad, the platen defining a cooling lumen.

15. A method of polishing a substrate, comprising:
flowing a polishing slurry into a slurry delivery lumen of a heat exchanger;
flowing a cooling fluid into a cooling lumen of the heat exchanger;
delivering the polishing slurry from the heat exchanger to a polishing pad; and
polishing a substrate atop the polishing pad.

16. The method of polishing a substrate of claim 15, wherein:
a temperature of the cooling fluid is between 5°C and 19°C.

17. The method of polishing a substrate of claim 15, wherein:
polishing the substrate comprises one or both of rotating the polishing pad and rotating the substrate.

18. The method of polishing a substrate of claim 17, further comprising:
monitoring a torque between the substrate and the polishing pad; and
adjusting one or both of a rotational speed of the polishing pad and a rotational speed of the substrate when the torque exceeds a predetermined threshold.

19. The method of polishing a substrate of claim 15, further comprising:
monitoring a temperature of the polishing pad; and
adjusting one or both of a temperature and a flowrate of the cooling fluid delivered from a cooling fluid source to the cooling lumen of the heat exchanger based on the temperature of the polishing pad.

20. The method of polishing a substrate of claim 15, wherein:
a flowrate of the cooling fluid is between 0.25 lpm and 2 lpm.
